(19) United States
(12) Patent Application Publication
(10) Pub. No.: US 2018/0142356 A1
(43) Pub. Date: May 24, 2018

(54) THICKNESS UNIFORMITY CONTROL FOR EPITAXIALLY-GROWN STRUCTURES IN A CHEMICAL VAPOR DEPOSITION SYSTEM

(71) Applicant: Veeco Instruments Inc., Plainview, NY (US)

(72) Inventors: Sandeep KRISHNAN, Jersey City, NJ (US); Michael CHANSKY, Plainview, NY (US); Daewon KWON, Whippany, NJ (US); Earl MARCELO, Plainview, NY (US)

(21) Appl. No.: 15/818,371

(22) Filed: Nov. 20, 2017

Related U.S. Application Data
(60) Provisional application No. 62/425,206, filed on Nov. 22, 2016.

(51) Int. Cl. C23C 16/52; C23C 16/34; H01L 29/20; H01L 21/02; H01L 21/66; H01L 21/67; H01L 29/205

(52) U.S. Cl. CPC C23C 16/52; C23C 16/34; H01L 29/2003; H01L 29/205; H01L 21/0254; H01L 22/26; H01L 21/67253; H01L 21/0262

(57) ABSTRACT

Systems and methods are described herein for improving the overall thickness control and the radial thickness profile of epitaxially-grown films or layers on wafers. Continuous, in situ measurement of thickness at a radially inner region and a radially outer region are used in embodiments to control corresponding precursor and/or dilution gas flow rates. Such measurements can be made using white light reflectometry through a viewport in the reactor housing.

### RELATED APPLICATION

The present application claims the benefit of U.S. Provisional Application No. 62/425,206 filed Nov. 22, 2016, which is hereby incorporated herein in its entirety by reference.

### TECHNICAL FIELD

Embodiments relate to Chemical Vapor Deposition (CVD) systems by decomposition of gaseous compounds, without leaving reaction products of surface material in the coating. More particularly, embodiments relate to processes and apparatuses adapted for the manufacture or treatment of semiconductor or solid state devices or of parts thereof.

### BACKGROUND

Chemical vapor deposition (CVD) is a process that can be used to grow desired objects epitaxially. Examples of current product lines of manufacturing equipment that can be used in CVD processes include the TurboDisc®, MaxBright®, EPIK®, and PROPEL® family of MOCVD systems, manufactured by Veeco Instruments Inc. of Plainview, N.Y.

A number of process parameters are controlled, such as temperature, pressure and gas flow rate, to achieve a desired crystal growth. Different layers are grown using varying materials and process parameters. For example, devices formed from compound semiconductors such as III-V semiconductors typically are formed by growing successive layers of the compound semiconductor using metal organic chemical vapor deposition (MOCVD). In this process, the wafers are exposed to a combination of gases, typically including a metal organic compound as a source of a group III metal, and also including a source of a group V element (for example, arsenic or phosphorus) which flow over the surface of the wafer while the wafer is maintained at an elevated temperature. Generally, the metal organic compound and group V source are combined with a carrier gas which does not participate appreciably in the reaction as, for example, nitrogen or hydrogen. One example of an III-V semiconductor is gallium nitride (GaN), which can be formed by the reaction of gallium and nitrogen, aluminum nitride (AlN), which can be formed by the reaction of aluminum and nitrogen, or aluminum gallium nitride (AlGa₁₋ₓNₓ, where 0≤x≤1), which can be formed by the reaction of aluminum, gallium, and nitrogen. These materials form a semiconductor layer on a wafer made of a suitable substrate. Precursor and carrier gases containing gallium, aluminum, and nitrogen, for example, can be introduced by a gas injector (also called a showerhead) which is configured to distribute the gases as evenly as possible across the growth surface of the substrate. Other semiconductor layers, such as SiN, TiN, InGaN, GaAs and the like, which are formed from Group II, Group IV, Group V, and Group VI elements, can be formed and analyzed within the current system and method. Semiconductor layers formed from of the foregoing can be undoped, p-doped (with, for example, boron, aluminum, nitrogen, gallium, magnesium, and indium), or n-doped (with, for example, phosphorus, arsenic, and carbon).

The wafer is usually maintained at a temperature on the order of 500-1200° C. during deposition of precursor gases and related compounds. The precursor gases, however, are introduced to the chamber at a much lower temperature, typically 200° C. or lower. Thus, as the precursor gases approach the wafer, their temperature increases substantially. Depending on the precursor gases used in deposition of the particular wafer under construction, pyrolyzation of the precursor gases can occur at an intermediate temperature between that of the input gases and the wafer. This pyrolyzation facilitates the interaction of the precursor gases and growth of the crystal structure. This crystal structure grows, epitaxially, until a desired thickness is reached.

In a MOCVD process chamber, semiconductor wafers can be grown as single wafers on a susceptor (also called a wafer carrier). Alternatively, in so-called “batch” process chambers, layers of thin film are grown on multiple wafers placed in pockets of a wafer carrier, to provide a uniform exposure of their surfaces to the atmosphere within the reactor chamber for the deposition of the semiconductor materials. Rotation speed is often on the order of 1,000 RPM. The susceptors are typically machined out of a highly thermally conductive material such as graphite, and are often coated with a protective layer of a material such as silicon carbide.

In growing various epitaxial or semiconductor layers on the wafer, the precursor and carrier gas flows are generally downward (that is, perpendicular) to the surface of a wafer carrier along an increasing temperature gradient until it reaches pyrolyzation temperatures, then impinges upon the wafer surface(s) that are being grown. To maximize device yield, the thickness of epitaxial layers must be as uniform as possible across the entire area of the wafer. In addition the thickness must be repeatable across runs and systems. Conventionally, this is achieved by examining the results of a previous run and using prior experimental data (sensitivity curves) to adjust gas flows. From this data, an operator can attempt to improve the uniformity or achieve target thickness in the next run. This process is repeated until the uniformity and target thickness is judged to be “good enough” or as good as possible, at which point the recipe is “locked in” and future uniformity variation depends on the repeatability of the system. In other types of MOCVD systems, the precursor and carrier gas flow can also be parallel to the surface of the wafer carrier as well as having one or more precursor and carrier gases flowing downward (perpendicular) to the surface of the wafer carrier while having other precursor and carrier gases flow horizontal to the surface of the wafer carrier.

In order to control the absolute thickness of the epitaxial layer grown on the wafer, the concentration of precursor gas at the surface, as well as the temperature at the surface, can be controlled. The radial uniformity of deposition across the radius of the wafer carrier can be controlled by independently modulating the precursor and dilution flows at the radially inner or outer portions of the reactor, such as by operating various injectors at different rates or precursor gas compositions. In this embodiment, this independent control can be achieved using precursor or dilution flow control out of a diametrically situated flow inlet in the gas injector (typically aligned with the viewport of the system and called “viewport flow” henceforth). Modulating flow from a diametrical flow inlet in a rotating system can produce a larger response in the center than outer radii. For example, using such a flow control technique in a single-wafer system, the radially inner portions of a layer growing on the wafer could have a different layer thickness than the radially outer portions of the layer on the wafer. Likewise, in batch systems, the radially inner rings of pockets could grow layers having different layer thicknesses than those layers grown in the outer pockets.

The extent of uniformity improvement of layer thicknesses on a wafer based on changes to the flow rates or compositions is limited in a batch reactor with multiple wafers. In order to make any corrections, it is necessary to collect useful data on the thickness of each layer that has been grown. Conventionally, this is accomplished by removing the wafer from the reactor chamber and measure layer thicknesses by using film thickness measurement techniques such as spectroscopic reflectometry and ellipsometry. However, resolving individual thin layer thickness is extremely difficult due to technical limitation. Often times, total thickness of all layers is the only reliable information that ex situ measurements can provide. In situ spectroscopic reflectometry that uses white light source provides individual layer thickness because it measures the thickness variation in real time. Other techniques such as in situ discrete wavelength reflectometry or ellipsometry also can be used to determine thickness as well.

Tuning can be accomplished by manually adjusting a system, such as a dual-knob flow control. One such control system is described in U.S. Pat. No. 4,980,204. As described therein, an operator can adjust the source material gases to form a semiconductor layer having a desired thickness and composition. The controls can modify the gas flow rate through each of a series of adjustable or controllable vent pipes.

Manual adjustments based on individual measurements across the epitaxially grown layer can be used to control total epitaxial layer thickness. Non-uniformities in the epitaxially grown layer, however, cannot be corrected for by such manual adjustment. If adjustments such as those described in U.S. Pat. No. 4,980,204 were used to correct for non-uniformities, this could result in an accompanying, unwanted change in the radial thickness profile. If the thickness varies from the predetermined target, then the flow rates can be varied at inner and outer portions of the reactor chamber for the next wafer or batch run. A single wafer reactor conventionally provides a much better capability to tune layer thickness on each wafer, due to the axisymmetric nature of both the growth non-uniformity as well as the use of tuning knobs. An example of a conventionally used tuning knob is differential flow injection that can change the flow through the center injector alone, or a differential flow injector that can change the flow to the radially outer nozzles alone. These changes also necessarily result in a change to the radial profile thickness along the wafer when changed in isolation, as described above.

Additionally, the flow rates of certain species, or layer duration can be enhanced to change the overall thickness or growth rate. Like changes to the flow rates, changing concentration can change the overall growth rate, and consequently the layer thickness.

Accordingly, conventionally these tools have been used to tune the thickness over several calibration runs until an acceptable thickness profile as well as absolute thickness is generated.

It is therefore desirable to provide a system capable of eliminating the manual iteration needed in conventional systems to tune thickness uniformity. It is also desirable to eliminate the qualitative nature of such tuning, and to adjust uniformity automatically within the run to reduce or eliminate ‘scrap runs’ having unacceptable thickness variations. It is further desirable to improve run-to-run and system-to-system repeatability.

### SUMMARY

A thickness profile of an epitaxially-grown layer on a wafer can be controlled by a system that continuously adjusts a flow profile in a reactor.

According to an embodiment, a method controls a thickness profile of an epitaxially-grown layer. The method includes providing a reactor comprising a controller, a radially inner gas injector, and a radially outer gas injector. The method also includes determining, at the controller, at least two precursor and/or dilution gas flow rates wherein a first precursor and/or dilution gas flow rate is associated with the radially inner gas injector, and a second precursor and/or dilution gas flow rate is associated with the radially outer gas injector. A precursor and/or dilution gas is supplied at each of the radially inner gas injector and the radially outer gas injector based on the determined at least two precursor and/or dilution gas flow rates to grow the layer. The method includes illuminating a radially inner track of the layer and illuminating a radially outer track of the layer with a white light source via an optically-transparent viewport arranged in the reactor. The method includes detecting the illumination from the white light source as reflected off each of the radially inner track of the layer and the radially outer portion of the layer, and modifying the gas flow rates of at least one of the at least two precursor and/or dilution gas flow rates, based on the detected illumination.

According to another embodiment, a system for chemical vapor deposition includes a reactor. The reactor has a sealed housing having an optically-transparent viewport, a radially inner gas injector configured to deliver a first precursor and/or dilution gas, and a radially outer gas injector configured to deliver a second precursor and/or dilution gas. An optical system in communication with the optically transparent viewport includes a white light source arranged to direct light through the viewport and towards both a radially inner portion of a wafer and/or layer stack, and a radially outer portion of the wafer and/or layer stack. A detector system is configured to receive the light reflected from the radially inner portion of the wafer and the light reflected from the radially outer portion of the wafer. A controller is configured to adjust at least one of the first precursor and/or dilution gas flow rates and the second precursor and/or dilution gas flow rates based on the detected reflected light from the radially inner portion of the wafer and the detected reflected light from the radially outer portion of the wafer.

According to another embodiment, a wafer is made by a process. The process includes providing a reactor comprising a controller, a radially inner gas injector defining a radially inner zone, and a radially outer gas injector defining a radially outer zone. The method further includes determining, at the controller, at least two precursor and/or dilution gas flow rates, wherein a first precursor and/or dilution gas flow rate is associated with the radially inner zone and a second precursor and/or dilution gas flow rate is associated with the radially outer zone. The method further includes supplying the precursor and/or dilution gas at the radially inner injector and the radially outer injector, and epitaxially growing a layer on the wafer, wherein the layer has a radially inner portion at the radially inner zone and a radially outer portion at the radially outer zone. The method further includes illuminating the radially inner portion of the layer and the radially outer portion of the layer with a white light source via an optically-transparent viewport in the reactor. The method further includes detecting the illumination from the white light source as reflected off each of the radially inner portion and the radially outer portion, and modifying the at least two precursors and/or dilution gas flow rates based on the detected illumination. The method further includes determining when the layer has a predetermined thickness and radial uniformity, and repeating the above steps until the wafer has been produced having a layer with a predetermined thickness and radial uniformity.

The above summary is not intended to describe each illustrated embodiment or every implementation of the present invention. The detailed description and claims that follow more particularly exemplify these embodiments.

### BRIEF DESCRIPTION OF THE DRAWINGS

Embodiments may be more completely understood in consideration of the following detailed description, in which:

FIG. 1A is a cross-sectional perspective view of a chemical vapor deposition reactor chamber, according to an embodiment.

FIG. 1B is a cross-sectional view of a chemical vapor deposition reactor chamber, according to an embodiment.

FIG. 2 is a plan view of a susceptor, depicting measurement zones, according to an embodiment.

FIG. 3A is a contour map of a wafer and layers thereon, made using prior art measurement and correction techniques.

FIG. 3B is a contour map of a wafer and layers thereon, made according to an embodiment.

FIG. 3C is a contour map of a wafer and layers thereon, made according to an embodiment.

FIGS. 4A-4C depict methods for forming layers on a wafer, according to an embodiment.

FIG. 5 is a chart depicting thickness profiles of layers on wafers, including those made according to embodiments.

While embodiments are amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION OF THE DRAWINGS

In embodiments, the thickness and uniformity of a Chemical Vapor Deposition (CVD) system can be monitored and controlled in situ during deposition to eliminate wasteful calibration runs, and to improve overall thickness and radial thickness profile uniformity.

In a single-wafer embodiment, two optical detectors are positioned to measure the thickness of epitaxial growth on the susceptor. The optical detectors are aimed at two different radial positions of the susceptor. Based on the detected thickness at these two radial positions, the concentration and/or flow rate of precursor gas introduced to the CVD reactor chamber is modified. These modifications enhance uniformity of thickness across the wafer, and increase precision of the total thickness of the wafer and the layers grown thereon. Furthermore, the run-to-run uniformity of the layers grown on such wafers can be increased. According to embodiments, detectors can be arranged to use the viewport which is constructed on many conventional reaction chambers, and to use optical metrology devices to measure, in situ, the thickness of grown and growing films.

An in situ thickness measurement can be made at each of two radii on a wafer in a single wafer rotating system while an epitaxial film is being grown. Based on these two measurements the “center” gas flows at the center of the wafer will be adjusted to tune the uniformity. This adjustment may be applied to the next run or may be continually applied to the run in progress. Alternatively, other flows can be relatively adjusted to produce a ‘radial tuning effect.’ These measurements can be made at regular intervals or even continuously during epitaxial growth, to prevent growth that is non-uniform, or the wrong absolute thickness.

For AlGaN layers, for example, changing the flows changes both the thickness uniformity as well as the uniformity of the composition (that is, the aluminum-to-gallium ratio in the grown material). An analytically or experimentally determined model of how flow impacts composition may be developed and factored into the adjustment of flows made to achieve thickness uniformity. Similar models of response can be developed for uniformities of any layer.

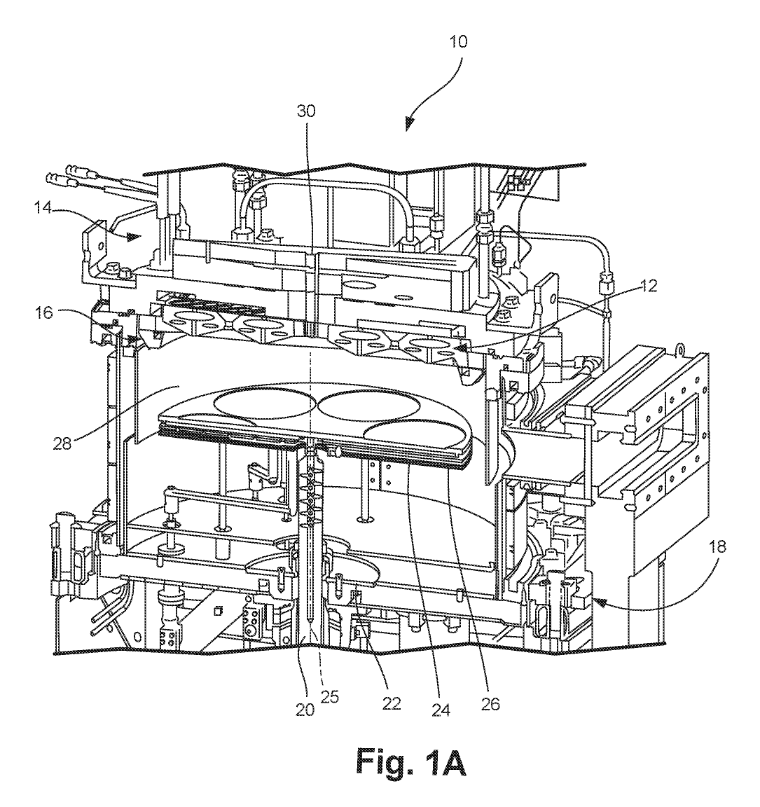

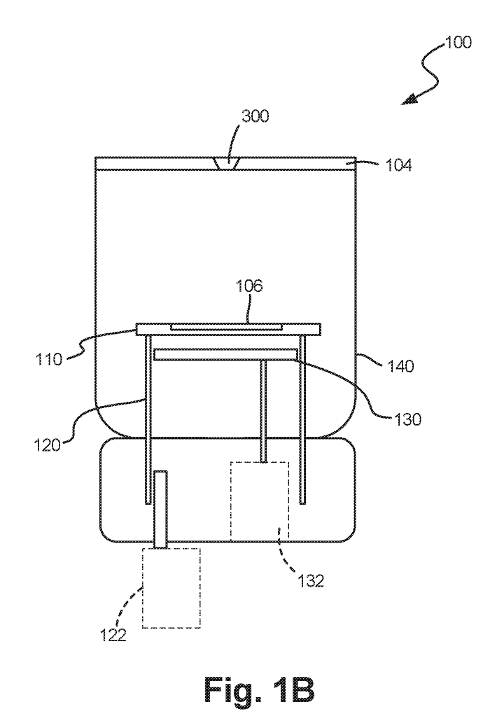

FIG. 1A illustrates a chemical vapor deposition apparatus in accordance with one embodiment of the invention. Reaction chamber 10 defines a process environment space. Gas injector 12 is arranged at one end of the chamber. The end having gas injector 12 is referred to herein as the “top” end of reaction chamber 10. This end of the chamber typically, but not necessarily, is disposed at the top of the chamber in the normal gravitational frame of reference. Thus, the downward direction as used herein refers to the direction away from gas injector 12; whereas the upward direction refers to the direction within the chamber, toward gas injector 12, regardless of whether these directions are aligned with the gravitational upward and downward directions. Similarly, the “top” and “bottom” surfaces of elements are described herein with reference to the frame of reference of reaction chamber 10 and gas injector 12.

Gas injector 12 is connected to precursor gas source 14 for supplying process gases to be used in the wafer treatment process, such as a carrier gas and reactant gases, such as a metalorganic compound and a source of a group V metal. Gas injector 12 is arranged to receive the various gases and direct a flow of process gases generally in the downward direction. Gas injector 12 desirably is also connected to coolant system 16 arranged to circulate a liquid proximate to gas injector 12 so as to maintain gas injector 12 at a desired temperature during operation. A similar coolant arrangement (not shown) can be provided for cooling the walls of reaction chamber 10. Reaction chamber 10 is also equipped with exhaust system 18 arranged to remove spent gases from the interior of the chamber 10 so as to permit continuous flow of gas in the downward direction from gas injector 12.

Spindle 20 is arranged within chamber 10 so that the central axis of spindle 20 extends in the upward and downward directions, as shown in FIG. 1A. Spindle 20 is mounted to chamber 10 by a conventional rotary pass-through device 22 incorporating bearings and seals so that spindle 20 can rotate while maintaining a seal between spindle 20 and the wall of reaction chamber 10. In alternative embodiments, in lieu of a spindle, a cylindrical jar drive can be used.

Spindle/jar drive 20 is coupled to susceptor 24 at its top end, i.e., at the end of spindle 20 closest to gas injector 12. Susceptor 24 can be a wafer carrier retention mechanism adapted to releasably engage a wafer carrier, in embodiments. Spindle 20 can be connected to a rotary drive mechanism such as an electric motor drive, which is arranged to rotate spindle 20 at the desired speed to cause susceptor 24 to rotate as well.

Susceptor 24 has a generally circular cross-section, arranged about central axis 25. In the embodiment shown in FIG. 1A, reactor chamber 10, gas injector 12, coolant system 16, spindle 20, susceptor 24, and heating element 26 are each arranged such that they are symmetrical about central axis 25. Susceptor 24 is a device upon which layers can be grown epitaxially on wafers.

Heating element 26 is mounted within chamber 10 and surrounds spindle 20 below susceptor 24. In a conventional MOCVD process, heating element 26 is actuated, and a rotary drive mechanism operates to turn spindle 20 and hence susceptor 24 at the desired speed. Typically, spindle 20 is rotated at a rotational speed from about 50-1500 revolutions per minute. Precursor gas source 14 can be actuated to supply gases through gas injector 12. The gases pass downwardly toward susceptor 24, over top surface 28 of susceptor 24, and around the periphery of the wafer(s) placed on the top surface 28 then carried to exhaust system 18. Thus, the top surface of the wafer mounted on susceptor 24 is exposed to a process gas including a mixture of the various precursor gases supplied by the process gas supply system 14. Most typically, the process gas at the top surface is predominantly composed of a carrier gas. In a typical chemical vapor deposition process, the carrier gas may be nitrogen, and hence the process gas at the top surface of the wafer carrier is predominantly composed of nitrogen with some amount of the reactive gas components.

Heating element 26 transfers heat to susceptor 24, principally by radiant heat transfer. In alternative embodiments, it may be possible to heat susceptor 24 by some other mechanism, such as inductive heat transfer. The heat applied to susceptor 24 flows upwardly through the body of susceptor 24 to the top surface 28 thereof. Heat is radiated from the top surface 28 to the colder elements of the chamber 10 such as, for example, to the walls of the process chamber and to gas injector 12. Heat is also transferred from the top surface 28 of wafer carrier 24 and the top surfaces of the wafers to the process gas passing over these surfaces.

FIG. 1B illustrates an alternative embodiment of a chemical vapor deposition apparatus 100 in accordance with another embodiment of the invention. Whereas FIG. 1A depicted a multi-wafer reactor system, FIG. 1B depicts a single-wafer reactor system.

Reactor chamber 140 defines a process environment space similar to that provided for reactor chamber 10 discussed above in FIG. 1A. Gas injector 104 is constructed and positioned similarly in chamber 140 of FIG. 1B as gas injector 12 is arranged in chamber 10 in FIG. 1A. Like gas injector 12 previously described with respect to FIG. 1A, gas injector 104 is connected to a precursor gas source (not shown) for supplying process gases to be used in the wafer treatment process, such as a carrier gas and reactant gases, such as a metalorganic compound and a source of a group V metal. Similar to gas injector 12 of FIG. 1A, gas injector 104 is desirably connected to a coolant system (not shown) to circulate a liquid proximate to gas injector 104 so as to maintain gas injector 104 at a desired temperature. A similar coolant arrangement (not shown) can be provided for cooling the walls of reaction chamber 140. Reaction chamber 140 is also equipped with exhaust system (not shown) arranged at the bottom of chamber 140 to remove spent gases from the interior of the chamber 140 so as to permit continuous flow of gas in the downward direction from gas injector 104.

Jar drive assembly 120 is arranged within chamber 140 so that the central axis of susceptor 110, which is mounted to jar drive assembly 120, extends in the upward and downward directions. Jar drive assembly 120 is mounted to chamber 140 by a conventional pass through device (not shown) so that a seal is maintained between the jar drive assembly 120 and the wall of chamber 140. Jar drive assembly 120 is rotated by jar drive motor 122.

Susceptor 110 is coupled to the top end of jar drive assembly 120, so that the top surface of susceptor 110 is closest to gas injector 104. Susceptor 110 can be a single wafer carrier retention system holding a single wafer 106 or can support multiple wafers.

Susceptor 110 has a generally circular cross-section, arranged about a central axis and the chamber 140, heater 130, and gas injector 104 are also arranged such that they are symmetrical about the same central axis.

Heater 130 is mounted within chamber 140 and below susceptor 110. In a conventional MOCVD process, heater 130 is actuated and jar drive motor 122 operates to rotate jar assembly 120 at the desired speed. In embodiments, jar drive assembly is rotated at a rotational speed from about 50 to about 1500 revolutions per minute. A precursor gas source can be actuated to supply gases through gas injector 104. The gases pass downwardly toward susceptor 110 and flow across the surface of wafer 106 and then are carrier to the exhaust system. Thus, the top surface of wafer 106 is exposed to a process gas including a mixture of the various precursor gases supplied by the process gas supply system. In embodiments, the process gas at the top surface is predominantly composed of a carrier gas. In one embodiment of a chemical vapor deposition process, the carrier gas may be nitrogen, and hence the process gas at the top surface of the wafer carrier is predominantly composed of nitrogen with some amount of the reactive gas components.

Heater 130 is configured to transfer heat to susceptor 110, principally by radiant heat transfer. In alternative embodiments, it may be possible to heat susceptor 110 by some other mechanism, such as inductive heat transfer. The heat applied to susceptor 110 flows upwardly through the body of susceptor 110 to the top surface thereof. Heat is radiated from the top surface of susceptor 110 to the colder elements of the chamber 140 such as, for example, to the walls of the chamber 140 and to gas injector 104. Heat is also transferred from the top surface of susceptor 110 and the top surface of wafer 106 to the process gas passing over these surfaces.

A window or viewport (item 30 in FIG. 1A; item 300 in FIG. 1B) is arranged in the top surface of reactor housing 10 or reactor 140, which maintains a seal to prevent egress of the precursor gases while allowing optical measurements into the reactor chamber. As described in more detail below, the system described herein, which is in communication with viewport 30 or 300, can be used to take measurements of thickness of a semiconductor layer grown on the wafer at two or more radial positions. These data can be used to make corrections in real time to the thickness and radial profile of the semiconductor layer.

An in situ thickness measurement can be made at two radii on the wafer in a single wafer rotating system (for example, the system shown in FIG. 1B) while the epitaxial film is being grown. Based on these two measurements the “center” or “viewport” gas flows at the center of the wafer can be adjusted to tune the uniformity. This adjustment can be applied to the next run or can be continually applied to the run in progress. Alternatively, other flows can be relatively adjusted to produce a radial tuning effect.

For AlGaN layers, for example, changing the flow rates of the radially inner and outer precursor gas inputs independently changes the thickness uniformity. In addition, the uniformity of the composition (that is, the aluminum-to-gallium ratio in the grown material) also changes as the inner and outer flows are varied. An analytically or experimentally determined model of how flow impacts composition can be developed, in embodiments, and that model can be used to calculate a proper adjustment for those flow rates to maintain composition while achieving thickness uniformity. Similar models of response can be developed for uniformities of other layers having different compositions or thicknesses.

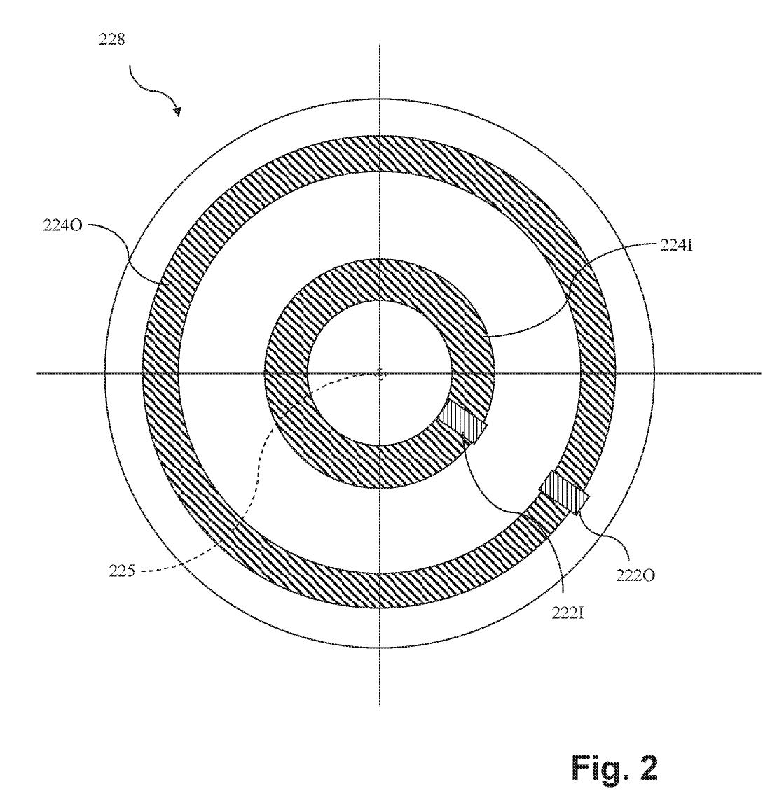

FIG. 2 is a plan view of a top surface 228 of a wafer. Top surface 228 is radially centered about central axis 225. Top surface 228 is analogous to top surface 28 previously described with respect to FIG. 1, and central axis 225 is analogous to central axis 25. Top surface 228 is configured to rotate about central axis 225 in a reactor chamber, exposed to precursor gases to promote epitaxial growth thereon.

Target regions, inner target 222I and outer target 222O, are arranged radially outward from central axis 225. In the embodiment shown in FIG. 2, inner and outer targets 222I and 222O are aligned with one another on a line extending radially outward from central axis 225. In alternative embodiments, the targets 222I and 222O could be arranged at any of a variety of positions, so long as they are at different radial positions from one another. In further embodiments, more than two targets could be arranged on top surface 228.

Inner target 222I is associated with inner track 224I. Likewise, outer target 222O is associated with outer track 224O. These tracks 224I and 224O are the portion of top surface 228 that passes targets 222I and 222O, respectively, during rotation of top surface 228 about central axis 225. Inner target 222I and outer target 222O are targets for light directed towards top surface 228. For example, in one embodiment a light source can be arranged outside of reactor chamber 10 of FIG. 1, with light directed through window 30 towards inner target 222I and outer target 222O. In one embodiment, the light can be “white light,” or full-spectrum. Based on the spectrum of reflected light, the thickness at each of inner target 222I and outer target 222O can be ascertained.

Based on the in situ thickness measurement, some combination of the measurements (for example, an average or smoothing) can be used to determine if the target thickness is achieved. The target can be achieved either by adjusting the flows of reactants to change the growth rate or by ending growth completely (that is, moving to the next recipe step) upon reaching the target thickness.

In addition, based on the two radii thickness measurement, the center injector or viewport flow can be independently controlled in relation to the total flow to achieve thickness profile uniformity in the radial direction. In another embodiment, there can be more than two radii of thickness measurement. In other embodiments the center flow can be controlled to generate a desired non-uniform profile based on the application.

This method for generating a uniform layer of the desired thickness can be implemented, in embodiments, using conventional reflectometers to measure growth of thick layers such as C-GaN or AlGaN buffers. In embodiments, a white light spectroscopic reflectometer can measure thin layers such as the AlGaN barrier in a traditional High Electron Mobility Transistor (HEMT) device, for example.

Furthermore, in open loop systems, new precursor flow rates can be determined to update a recipe used for the precursor or dilution gas flows. For example, in embodiments certain secondary chemical species can be added to account for any compositional shifts due to thickness control measures taken by the system. Furthermore, in embodiments multiple layers can be built up, epitaxially grown on top of one another, and the various layers may have different chemical compositions. In some systems, thickness control mechanisms such as those described herein can be used to determine when the recipe should be altered in order to begin growing a subsequent layer on top of an earlier layer that has reached its predetermined desired final thickness.

In embodiments, a closed loop control system can be implemented that increases center dilution flow in order to dilute precursors for reducing center thickness or that decreases center dilution flow for increasing center thickness. In embodiments, a series of experiments can be performed to measure the effect of adjustments to the center flow. These changes in flow rate or concentration, as well as the resulting impact on uniformity and thickness, can be observed and stored a database to predict what adjustment is needed to achieve a desired change in the uniformity. The experimental results can be used to verify modeling of thickness uniformity that could further enhance the database without more experiments being run, in embodiments.

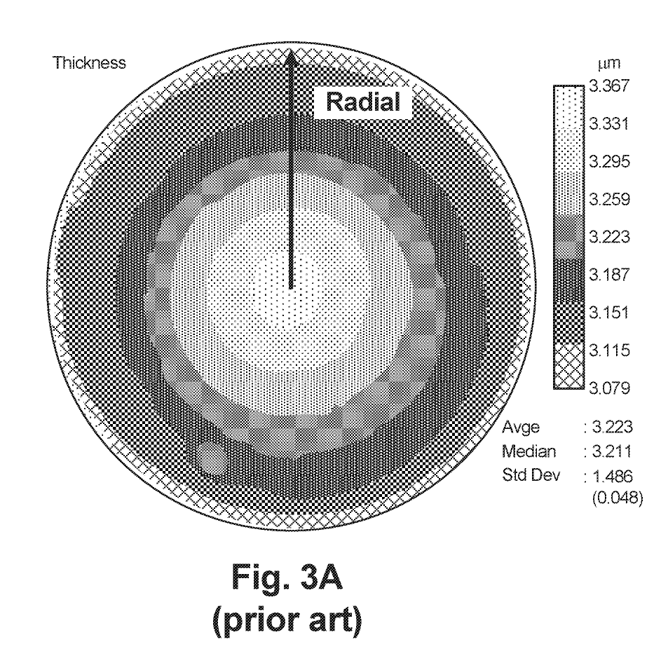

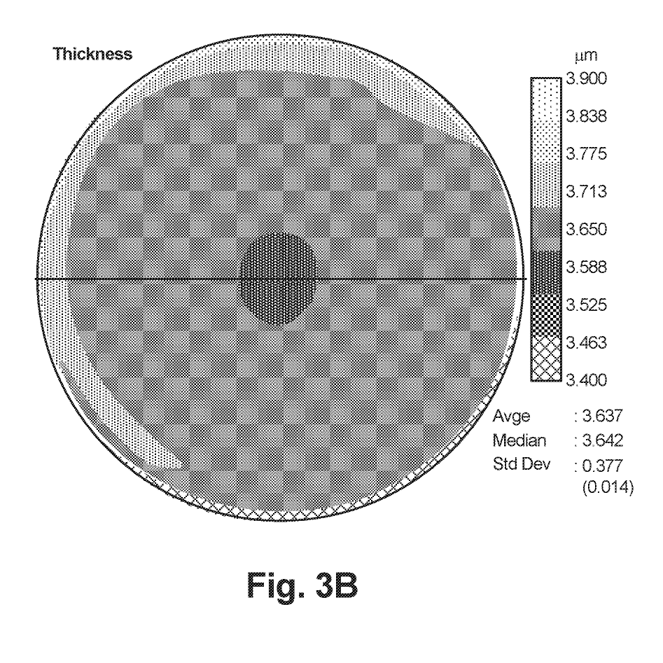

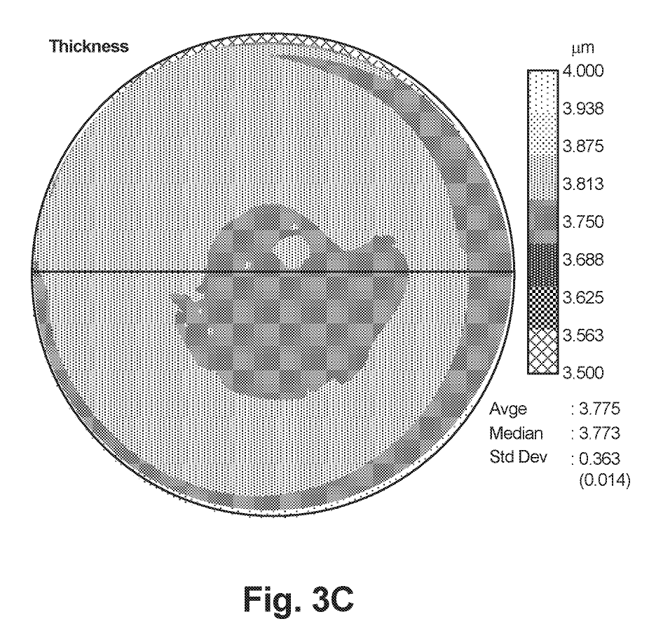

FIG. 3A shows a thickness distribution of a layer made using a conventional epitaxial growth process. In this embodiment, the layer thickness is significantly higher in the center, and decreases with increasing radial distance from the center of the wafer. Typically, in a conventional system, a non-uniform layer thickness like this could be measured and process conditions such as center flow rate and/or concentration or radially outer flow rate and/or concentration can be modified to increase uniformity. Making such changes could take multiple process runs, and can also affect total thickness. Therefore, it may take multiple attempts to generate a layer or layer stack that is both the desired thickness and is also uniformly thick across the entire radial profile.

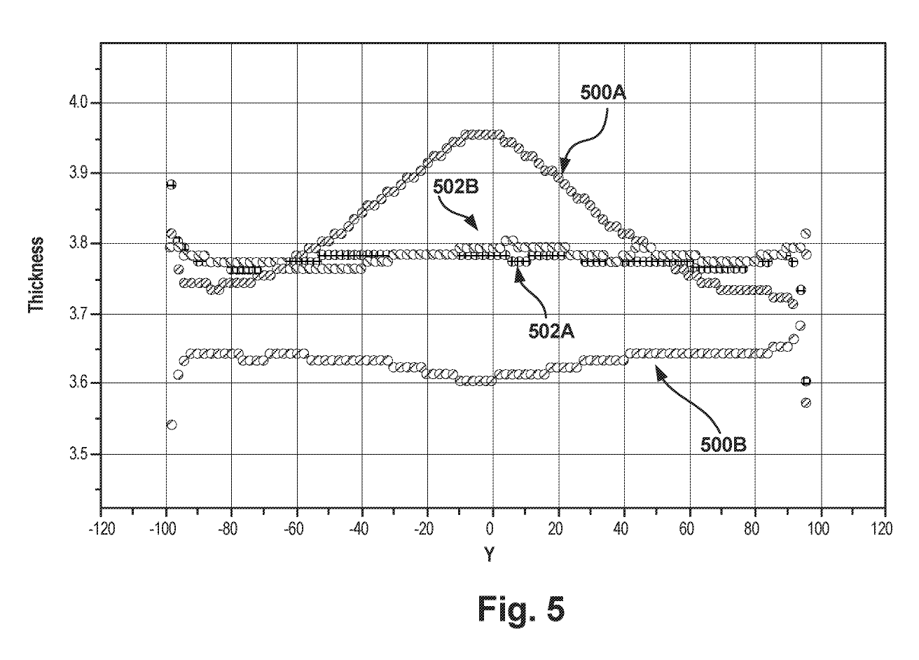

FIGS. 3B and 3C are thickness diagrams of two epitaxially grown layers according to embodiments. Not only are the thicknesses consistent with one another, but also the standard deviation of thickness is quite low. Therefore, in the embodiment of FIGS. 3A and 3B, there is both intra-layer thickness uniformity, and also there is also run-to-run uniformity in thickness of the two layers shown in FIGS. 3B and 3C. A graphical depiction of one cross-section of a thickness profile for one epitaxially grown layer is shown at FIG. 5.

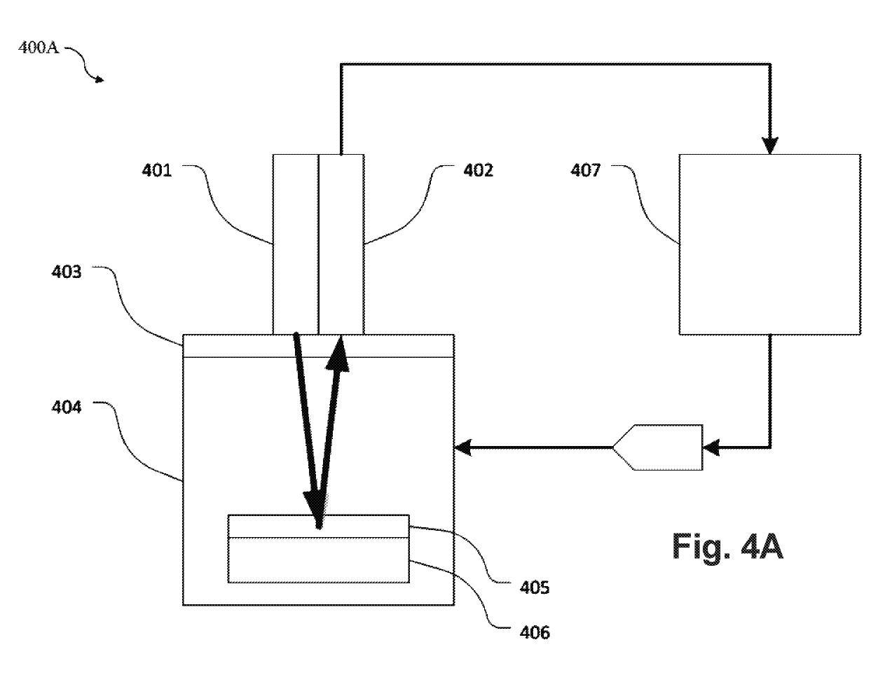

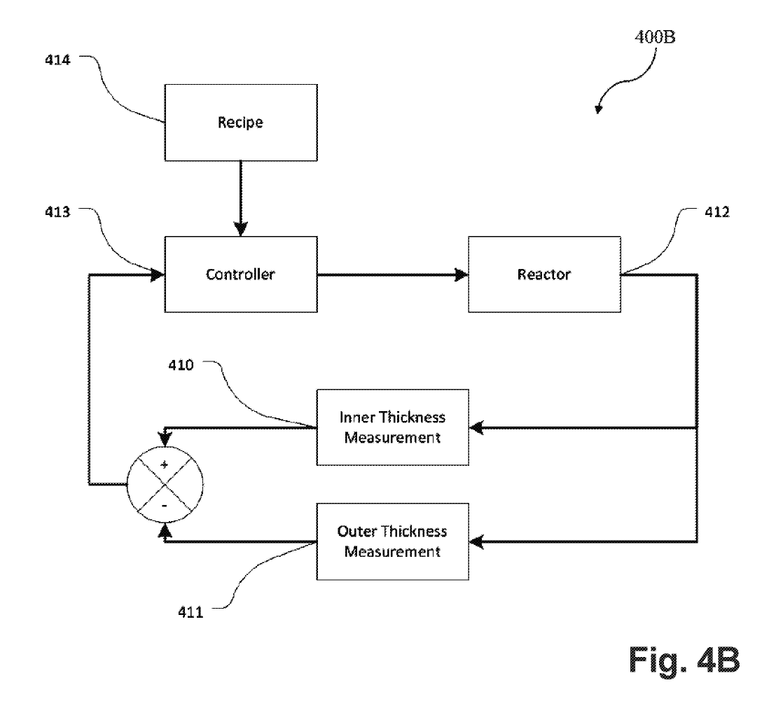

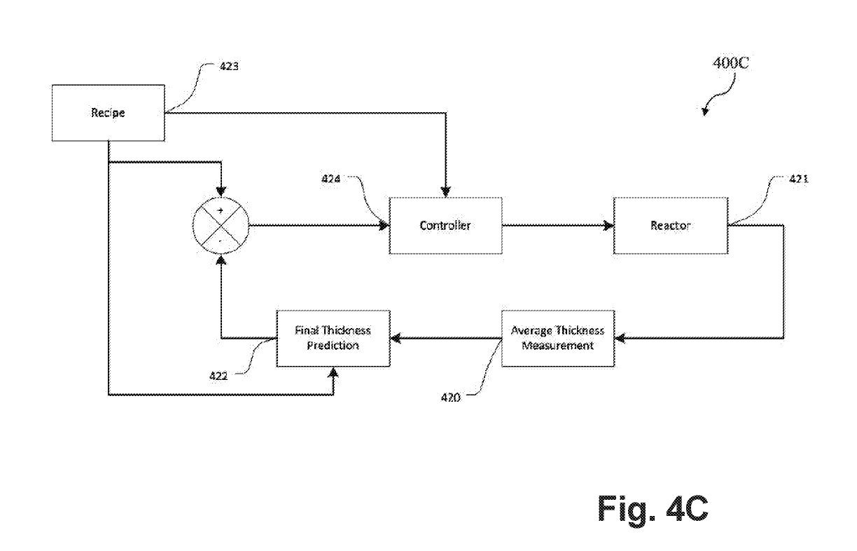

FIG. 4A is a schematic view of a system 400A for detecting reflected light as described above, to set a recipe or flow rates in accordance with a predetermined layer thickness and material distribution.

System 400A includes loading a recipe into a controller 407 configured to modify the flow of various precursors. As described above, controller 407 can modify the flow rate or the gas composition of a radially inner flowpath, a radially outer flowpath, or both, in embodiments.

Light source 401 directs while light through viewport 403 into reactor chamber 404. Light directed in this way illuminates epitaxial layer 405 being grown on wafer 406. The illuminated wafer reflects light back through viewport 403 into detector 402. Based on the measurement of the reflected light, controller 407 adjusts one or more flows to the reactor chamber 404.

It should be understood that while system 400A of FIG. 4A is a simplified schematic, various other alternatives or variations could be made. For example, light source 401 and detector 402 may be housed in a single assembly as shown, or may be separated. Furthermore, various viewport shapes and positions, and any number of additional light sources or detectors, may be used in embodiments to detect characteristics of layer 405 at other positions.

In embodiments, controller 407 can adjust flows to reactor chamber 404 in an automated fashion based on reflected light sensed at detector 402 and initial inputs for desired thickness and/or radial thickness uniformity. In alternative embodiments, controller 407 can also take into consideration user inputs that are provided at the start of the epitaxial growth process, such as desired final thickness, uniformity, or material composition profile. In still further embodiments, system 400A can intake contemporaneous user controls that are provided during epitaxial growth. In still further embodiments, including those where multiple layers are being grown in a common system having one or more chambers, detected reflection from various layers can be used in combination with one another to modify flow rates at each individual wafer. For example, in a batch reactor where some layers are growing faster than others, precursor gas flow could be reduced or the composition of the precursor gas could be changed to prevent the batch from having non-uniform thicknesses.

FIGS. 4B and 4C are flowcharts showing iterative, continuous processes 400B and 400C for controlling thickness and uniformity of epitaxially-grown layers, according to an embodiment.

FIG. 4B depicts process 400B, which is one method for operating a system such as system 400A of FIG. 4A. According to process 400B, a radially inner thickness measurement 410 and radially outer thickness measurement 411 are made based on reflectance from a layer in reactor 412, as described previously with respect to FIGS. 3 and 4A. A difference between those two measurements is determined to send to controller 413, which modifies gas flows provided by a user via recipe 414. The new gas flows to reactor 412 can cause a change in the growth rate of the layer, either to change the overall thickness or to change the radial thickness profile of the layer.

FIG. 4C depicts process 400C, in which an average thickness measurement 420 is made of a layer grown in reactor 421. The final thickness 422 is predicted using measurements of the thickness and the rate of increase of those measurements, in combination with a predetermined total time for which the layer will be grown as specified in recipe 423. Controller 424 modifies the gas flows provided at recipe 423, and those modified gas flows change the rate at which the layer grows in reactor 421. By iteratively adjusting these flows, controller 424 achieves a final thickness that is set by recipe 423, even if the total growth time varies from original estimates/inputs.

FIG. 5 depicts the layer thickness from four different wafers, according to embodiments. In each line, the operator attempted to make a 3.8 μm layer thickness having radially uniform thickness.

The first two wafers are associated with layer thickness lines 500A and 500B, and were made using conventional techniques. That is, the wafer associated with layer thickness line 500A was made first, and had a very high thickness at the radially inner portion. Due to this level of film thickness variation, the wafer is not suitable for use. Accordingly, the operator increased the radially inner flow rate of dilution gas to dilute the precursors and reduce the radially inner thickness.

Although the radially inner portion was made thinner after this adjustment, as shown in line 500B, the overall thickness of the layer also decreased between the two runs as a result of the adjustment. Furthermore, the adjustment slightly over-corrected the radially inner thickness, causing a trough rather than a peak at the radially inner portion of the wafer. Again, this layer on the wafer may not be sufficiently smooth, or it may not be sufficiently thick, to be used or sold.

The two runs shown as 502A and 502B are made using continuous feedback from a white-light source and reflectance measurements. Because layers grown in this fashion can be continuously monitored for thickness, the accuracy of overall thickness is significantly improved, and sits close to 3.8 μm in each case. Furthermore, because variations in radial thickness can be measured and corrected for during the run, the radial uniformity of thickness is significantly improved compared to the conventionally-produced layers. Both of the layers processed in this way are acceptable for use or sale, without using time and resources associated with post-production measurement and adjustment of the flow rates as is required based on the first runs using the conventional systems depicted by lines 500A and 500B.

In embodiments, overall thickness uniformity can be improved to better than what is available by conventional methods. For example, a conventional method might have a batch uniformity of thickness ranging by up to 1% coefficient of variation (CV) of a HEMT stack. Using the methods and systems described herein, thickness uniformity can be improved to less than 0.6% CV deviation, both on a particular wafer and within the overall batch, without manually intervening. In further embodiments, overall thickness uniformity across a batch can be improved to less than 0.3% CV without manually intervening.

Furthermore, in a HEMT stack including an AlGaN layer, the typical thickness requirement is between 20 and 40 nm, with a variation of 1 nm or less. Conventional systems cannot achieve this thickness without high levels of manual intervention and/or scrapping runs that are outside of this specification.

In alternative embodiments, various other thicknesses, materials, or layers can be produced. In some embodiments, multiple layers can be produced stacked on top of one another, and overall thickness and radial profile of each layer can be controlled.

Various embodiments of systems, devices and methods have been described herein. These embodiments are given only by way of example and are not intended to limit the scope of the invention. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the invention.

Persons of ordinary skill in the relevant arts will recognize that embodiments may comprise fewer features than illustrated in any one individual embodiment described above. The embodiments described herein are not meant to be an exhaustive presentation of the ways in which the various features of the invention may be combined. Accordingly, the embodiments are not mutually exclusive combinations of features; rather, alternative embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted. Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended. Furthermore, it is intended also to include features of a claim in any other independent claim even if this claim is not directly made dependent to the independent claim.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims for the present invention, it is expressly intended that the provisions of Section 112(f) of 35 U.S.C. are not to be invoked unless the specific terms “means for” or “step for” are recited in a claim.

1. A method for controlling a thickness profile of an epitaxially-grown layer, the method comprising:
providing a reactor comprising a controller, a radially inner gas injector, and a radially outer gas injector;
determining, at the controller, at least two precursor and/or dilution gas flow rates wherein,
a first precursor and/or dilution gas flow rate is associated with the radially inner gas injector; and
a second precursor and/or dilution gas flow rate is associated with the radially outer gas injector;
supplying precursor and/or dilution gas at each of the radially inner gas injector and the radially outer gas injector based on the determined at least two precursor and/or dilution gas flow rates to grow the layer;
illuminating a radially inner track of the layer and illuminating a radially outer track of the layer with a white light source via an optically-transparent viewport arranged in the reactor;
detecting the illumination from the white light source as reflected off each of the radially inner track of the layer and the radially outer portion of the layer; and
modifying the gas flow rates of at least one of the at least two precursor and/or dilution gas flow rates, based on the detected illumination.

2. The method of claim 1, wherein the detected illumination is indicative of a thickness of the layer.

3. The method of claim 2, further comprising determining the thicknesses of the layer at the radially inner track and at the radially outer track.

4. The method of claim 3, further comprising independently modifying the first precursor and/or dilution gas flow rate and the second precursor and/or dilution gas flow rate to enhance radial thickness uniformity of the layer.

5. The method of claim 3, further comprising stopping the growth of the layer when the layer has a predetermined final thickness.

6. The method of claim 3, further comprising adjusting the at least two precursor and/or dilution gas flow rates to achieve a predetermined final thickness of the layer or a desired growth rate.

7. The method of claim 1, further comprising updating a recipe used by the controller to determine the at least two precursor and/or dilution gas flow rates, based on the detected illumination.

8. The method of claim 7, wherein the updated recipe corresponds to a second layer having a different material composition than the layer, and epitaxially grown on the layer.

9. A system for chemical vapor deposition, the system comprising:
a reactor having:
a sealed housing having an optically-transparent viewport;
a radially inner gas injector configured to deliver a first precursor and/or dilution gas; and
a radially outer gas injector configured to deliver a second precursor and/or dilution gas;
an optical system in communication with the optically transparent viewport, the optical system comprising:
a white light source arranged to direct light through the viewport and towards both a radially inner portion of a wafer and a radially outer portion of the wafer;
a detector system configured to receive the light reflected from the radially inner portion of the wafer and the light reflected from the radially outer portion of the wafer; and
a controller configured to adjust at least one of the first precursor and/or dilution gas flow rates and the second precursor and/or dilution gas flow rates based on the detected reflected light from the radially inner portion of the wafer and the detected reflected light from the radially outer portion of the wafer.

10. The system of claim 9, wherein the detector system comprises a single detector arranged to receive light reflected from both the radially inner portion of the wafer and the radially outer portion of the wafer.

11. The system of claim 9, wherein the detector system comprises a first detector arranged to receive light reflected from the radially inner portion of the wafer, and a second detector arranged to receive light reflected from the radially outer portion of the wafer.

12. The system of claim 9, wherein the detector system is configured to determine a thickness of an epitaxially-grown layer on the wafer at each of the radially inner portion and the radially outer portion.

13. The system of claim 12, wherein the controller is configured to adjust at least one of the first precursor and/or dilution gas flow rate and the second precursor and/or dilution gas flow rate, based on the determined thickness of the epitaxially-grown layer at each of the radially inner portion and the radially outer portion, to produce a layer having a substantially uniform thickness.

14. The system of claim 12, wherein the controller is configured to adjust the at least one of the first precursor and/or dilution gas flow rate and the second precursor and/or dilution gas flow rate based on the determined thickness of the epitaxially-grown layer on the wafer at each of the radially inner portion and the radially outer portion to produce a final wafer having a desired total thickness.

15. The system of claim 12, wherein the detector system determines the thickness based on a reflectance as a function of wavelength.

16. The system of claim 9, wherein the controller is configured to adjust at least one of the first precursor and/or dilution gas flow rates and the second precursor and/or dilution gas flow rates continuously during epitaxial growth of the layer.

17. A wafer made by the process of:
providing a reactor comprising a controller, a radially inner gas injector defining a radially inner zone, and a radially outer gas injector defining a radially outer zone;
determining, at the controller, at least two precursor and/or dilution gas flow rates, wherein
a first precursor and/or dilution gas flow rate is associated with the radially inner zone; and
a second precursor and/or dilution gas flow rate is associated with the radially outer zone;
supplying the precursor and/or dilution gas at the radially inner injector and the radially outer injector;
epitaxially growing a layer on the wafer, wherein the layer has a radially inner portion at the radially inner zone and a radially outer portion at the radially outer zone;
illuminating the radially inner portion of the layer and the radially outer portion of the layer with a white light source via an optically-transparent viewport in the reactor;
detecting the illumination from the white light source as reflected off each of the radially inner portion and the radially outer portion;
modifying the at least two precursor and/or dilution gas flow rates based on the detected illumination;
determining when the layer has a predetermined thickness and radial uniformity; and
repeating the above steps until the wafer has been produced having a layer with a predetermined thickness and radial uniformity.

18. The wafer of claim 17, wherein the layer has a composition that is selected from the group consisting of:
AlGa₁₋ₓNₓ, wherein 0≤x≤1,
GaN,
AlN, and
undoped, p-doped, and n-doped layers of the foregoing, and mixtures thereof.

19. The wafer of claim 17, wherein the epitaxially-grown layers comprise a plurality of layers, and wherein at least two layers within the plurality include dissimilar material compositions from one another.
